(19) United States
(12) Patent Application Publication
(10) Pub. No.: US 2013/0155613 A1
(43) Pub. Date: Jun. 20, 2013

(54) ELECTRONIC DEVICE WITH AIR DUCT

(71) Applicants: YAO-TING CHANG, Tu-Cheng (TW); CHAO-KE WEI, Tu-Cheng (TW)

(72) Inventors: YAO-TING CHANG, Tu-Cheng (TW); CHAO-KE WEI, Tu-Cheng (TW)

(73) Assignee: HON HAI PRECISION INDUSTRY CO., LTD., Tu-Cheng (TW)

(21) Appl. No.: 13/337,262

(22) Filed: Dec. 26, 2011

(30) Foreign Application Priority Data
Dec. 20, 2011 (TW) 100147572

(51) Int. Cl. H05K 7/20

(52) U.S. Cl. 361/695

(57) ABSTRACT

An electronic device includes a casing, a motherboard installed in the casing, a number of components positioned on the motherboard, a number of fans and vents aligning with the components, and an air duct installed on the motherboard so as to enclose the components. The casing includes a cover defining an opening. The air duct includes a removable top plate covering the opening.

BACKGROUND

1. Technical Field

The disclosure relates to the cooling of electronic devices and, particularly, to an electronic device with an air duct for guiding airflow.

2. Description of Related Art

Many modern electronic devices, such as computers or servers, are becoming thinner and smaller, yet still hold more electronic components, such as central processing units (CPUs), memory cards, and south bridge chips. CPUs generate a large amount of heat during operation. The heat needs to be dissipated effectively to ensure the continued proper function of the electronic devices. A heat sink may be mounted on a CPU for dissipating the heat, augmented by a cooling fan to generate airflow, and an air duct(s) to guide the airflow. Therefore, the heat sink is made ever bigger to dissipate the increased heat, but the heat sink occupies much space in the air duct, which affects the cooling efficiency of the airflow through the air duct. Therefore, more efficient cooling structure is required, by means other than simply increasing the size of the heat sink.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric, exploded view of an embodiment of an electronic device, wherein the electronic device includes an air duct.

FIG. 2 is a partially enlarged view of the air duct of FIG. 1.

FIG. 3 is an assembled, isometric view of the electronic device of FIG. 1.

FIG. 4 is a sectional view of the electronic device of FIG. 3, taken along the line of IV-IV.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

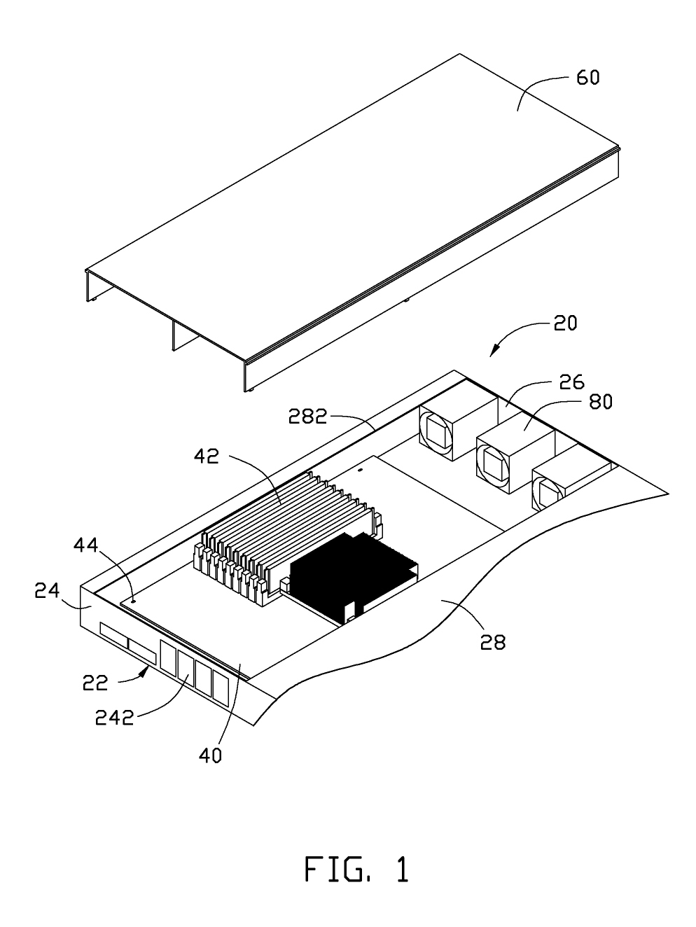

FIG. 1 shows an embodiment of an electronic device including a casing 20, a motherboard 40, an air duct 60, and a plurality of fans 80.

The casing 20 includes a bottom wall 22, a first end wall 24 perpendicularly extending up from a first end of the bottom wall 22, a second end wall 26 perpendicularly extending up from a second end of bottom wall 22 opposite to the first end wall 24, and a cover 28 on the tops of the bottom wall 22 and the first and second end walls 24 and 26. The first and second sidewalls 24 and 26 each define a plurality of vents 242. The motherboard 40 is installed on the bottom wall 22 adjacent to the first end wall 24. A plurality of components 42, such as expansion cards and a heat sink attached to a central processing unit, is mounted on the motherboard 40. The motherboard 40 defines a plurality of fastening holes 44 flanking the components 42. The fans 80 are installed to the second end wall 26, aligning with the components 42. The cover 28 defines an opening 282, for completely exposing the components 42.

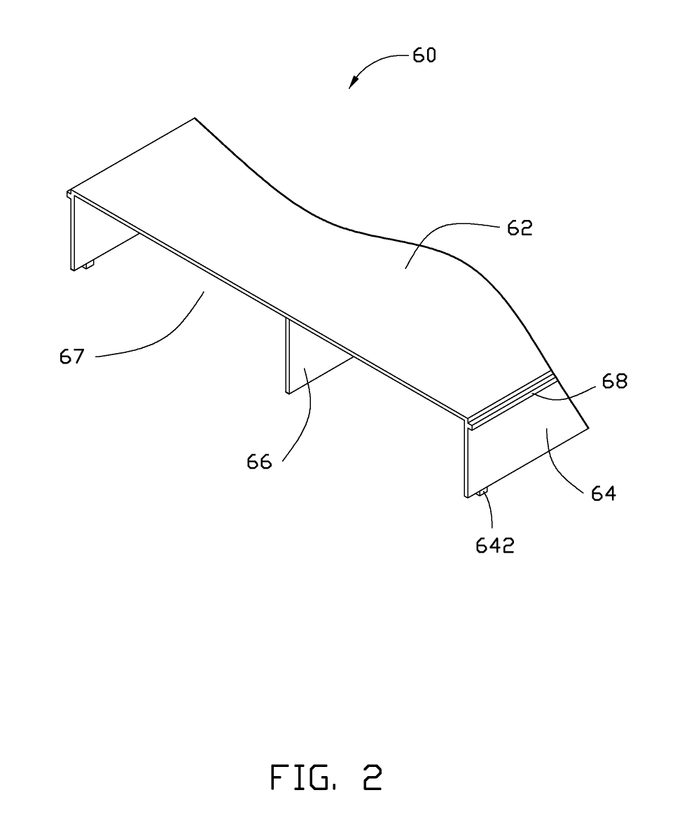

Referring to FIG. 2, the air duct 60 includes a top plate 62, two side plates 64 perpendicularly extending down from two opposite sides of the top plate 62, and a partition plate 66 extending down from the top plate 62 between and parallel to the side plates 64. When the air duct 60 is in place, the partition plate 66 and each side plate 64 cooperatively bound an airflow channel 67. A bar 68 protrudes out from each side plate 64, adjacent and parallel to the top plate 62. Two tabs 642 protrude down from a bottom side of each side plate 64 opposite to the top plate 62.

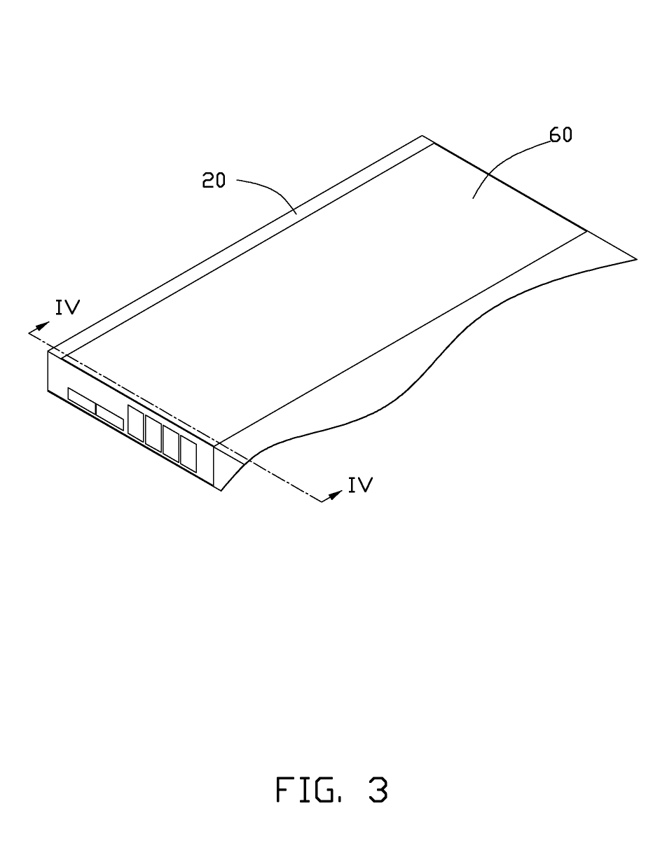

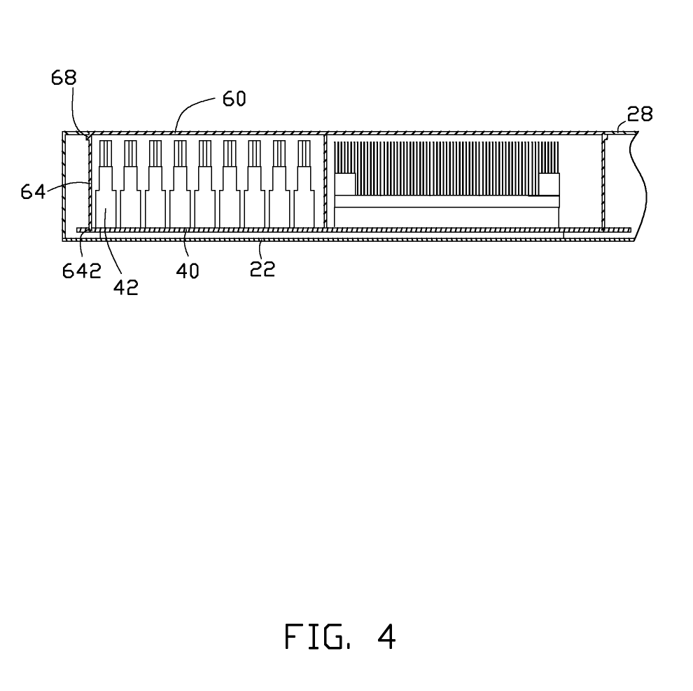

Referring to FIGS. 3 and 4, in assembly, the air duct 60 is attached to the casing 20 at the opening 282. The opposite ends of the airflow channels 67 align with the fans 80 and the vents 242. The tabs 642 are inserted into the fastening holes 44. The components 42 find themselves in the air flow channels 67. The top plate 62 covers the opening 282. A top surface of the top plate 62 is coplanar with a top surface of the cover 28. The bars 68 abut against an inner surface of the cover 28 at two opposite sides of the opening 282, so as to prevent the disengagement of the air duct 60 from the motherboard 40. The top plate 62 is coplanar with the cover 28, thereby creating more efficient airflows in the airflow channels 67 of the air duct 60.

It is to be understood, however, that even though numerous characteristics and advantages of certain embodiments have been set forth in the foregoing description, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. An electronic device, comprising:
a casing comprising a cover defining an opening;
a motherboard installed in the casing opposite to the opening, and comprising a plurality of components;
a fan aligning with the components; and
an air duct mounted on the motherboard to enclose the components, the air duct comprising a top plate covering the opening.

2. The electronic device of claim 1, wherein the air duct further comprises two side plates extending down from two opposite sides of the top plate, and a partition plate extending down from the top plate between and parallel to the side plates, each side plate and the partition plate cooperatively bound an airflow channel for receiving some of the components.

3. The electronic device of claim 2, wherein a bar protrudes out from each side plate adjacent to the top plate, for abutting against an inner surface of the cover at two opposite sides of the opening.

4. The electronic device of claim 2, wherein the motherboard defines a plurality of fastening holes, a plurality of tabs protrude from a bottom of each side plate opposite to the top plate, to be inserted into the corresponding fastening holes.

5. The electronic device of claim 1, wherein the top plate is coplanar with the cover.
